(19) United States
(12) Patent Application Publication
(10) Pub. No.: US 2001/0053600 A1
(43) Pub. Date: Dec. 20, 2001

(54) Methods for characterizing and reducing adverse effects of texture of semiconductor films

(76) Inventors: Guarionex Morales, Sunnyvale, CA (US); Lu You, San Jose, CA (US); Richard J. Huang, Cupertino, CA (US); Simon Chan, Saratoga, CA (US); Dawn Hopper, San Jose, CA (US)

Correspondence Address: FLIESLER DUBB MEYER & LOVEJOY, LLP, FOUR EMBARCADERO CENTER, SUITE 400, SAN FRANCISCO, CA, 94111, US

(21) Appl. No.: 09/773,312

(22) Filed: Jan. 31, 2001

Related U.S. Application Data
(60) Provisional application No. 60/179,274, filed on Jan. 31, 2000.

(51) Int. Cl. H01L 21/4763; H01L 21/44

(52) U.S. Cl. 438/627; 438/653

(57) ABSTRACT

Improved methods for manufacturing semiconductor devices incorporating barrier layers at metal/dielectric interfaces include the use of nitrogen-rich plasma, ion beam implantation and/or electromagnetic radiation to form regions of nitrided metal. The barrier layers decrease the diffusion of dopants such as fluorine, phosphorous and boron from the dielectric material into the metal, thereby decreasing the formation of metal salts. By decreasing the formation of metal salts, the barrier layers of this invention decrease the formation of voids and areas of delamination, and thereby decrease the loss of electrical reliability during manufacture and during use. Additional aspects of this invention include methods for monitoring the deposition of thin metal films using sheet resistance measurements, and further embodiments of this invention include methods for monitoring the surface texture of films that undergo phase transitions. Additional embodiments include methods for monitoring and calibrating the temperatures of manufacturing processes on the surfaces of semiconductor wafers. Thus, useful lifetimes of semiconductor devices can be increased, and the manufacture of reliable devices can be easier, less expensive and more reproducible.

### RELATED APPLICATION

This Application claims priority to U.S. Provisional Patent Application Serial No: 60/179,274, filed Jan. 31, 2000 entitled “Methods for Characterizing and Reducing Adverse Effects of Texture of Semiconductor Films.” The above Provisional Patent Application is incorporated herein filly by reference.

### BACKGROUND OF THE INVENTION

1. Field of the Invention

This invention relates generally to the field of semiconductor manufacture, and more particularly, to the manufacture of metal features having barrier layers to decrease unwanted diffusion of dopant materials into the metal, to determining the texture and phase transitions of semiconductor films, and to methods for calibrating thermal processing equipment.

2. Description of the Related Art

As semiconductor devices become smaller to accommodate increased computer processing speeds and to decrease costs, it is becoming increasingly important to provide more efficient manufacturing methods to improve the quality of semiconductor films. Problems of semiconductor films can result from the physical structure of the films, which can be reflected in film texture. “Texture” means the molecular and crystalline structures of the film. Most semiconductor films comprise regions of crystalline and non-crystalline domains. Several specific types of problems can be caused by undesirable textures. Some areas in which texture can be important are (1) at interfaces between layers, (2) within the layer, and (3) at the surface of a layer.

It can be advantageous to provide adequate insulation between different layers to decrease cross-talk and leakage of electrical current between circuit elements. For example, the commonly used dielectric material, silicon dioxide (SiO₂) can be deposited between layers as an interlayer dielectric material (“ILD”). SiO₂ layers typically have a dielectric constant (K) of about 4.0. As device dimensions decrease, it can be desirable to provide dielectric materials having lower dielectric constants than 4.0.

One way of providing better electrical insulation having reduced dielectric constants is through the use of fluorinated dielectric materials. Fluorine in a dielectric material can provide “electron traps” which can reduce the polarizability of the dielectric material. By decreasing the polarizability of the dielectric material, the dielectric constant can be reduced, thereby providing improved insulating capabilities.

The addition of fluorine to SiO₂ can result in the formation of SiOF, and when in the form of a fluorinated glass, can have a dielectric constant of about 3.0 -3.8. By incorporating fluorinated glass into electrical insulating materials, such as interlevel and intermetal dielectrics (“IMD”), the insulating properties of the material can be improved. The decrease in dielectric constant of fluorinated glasses permits the manufacture of active semiconductor devices having smaller dimensions and increased device density. Moreover, by improving the electrical performance of dielectric materials, the useful lifetimes of semiconductor devices can be increased.

Fluorinated SiO₂ can be formed by the diffusion of either fluorine gas (F₂), NF₃ or SiF₄ gas into preformed glass, forming fluorinated silicate glass, or “FSG” at temperatures typically in the range of several hundreds of degrees C. Alternatively, FSG can be made using vapor deposition methods using thermal or plasma energy to create reactive intermediates. The inclusion of F₂, NF₃ or SiF₄ into a mixture of precursors, including by way of example only, tetraethoxysilane (“TEOS”) can result in formation of a mixture of silica precursors and fluorine moieties. When deposited on a surface of a semiconductor wafer, the precursors and fluorine moieties can form a layer of FSG. FSG can also be manufactured using spin-on methods. Typically, the concentration of F in FSG is below about 3% to about 10%, alternatively about 5%.

In addition to incorporating fluorine into insulating materials, it can be desirable to manufacture dielectric materials incorporating dopants including phosphorous (P) and boron (B) to confer desired electrical properties to the SiO₂.

The insulating dielectric materials can be in direct contact with metal features, such as conductive lines and vias, thereby forming an interface between the metal and the dielectric material. This interface can be the site of problems, including metal salt formation, fluorine diffusion and dopant diffusion, each of which can degrade performance of the interface and can decrease reliability of semiconductor devices.

### I. Metal Salt Formation

The quality of the interface between the metal and insulators can limit the minimum size and useful lifetime of semiconductor devices. As doped dielectric materials are increasingly used because of their advantageous electrical properties, problems can be manifest at the interface between metal and dielectric materials. For example, fluorine, boron, and phosphorous can react with conductive metals such as aluminum to form metal salts. The structures of the metal salt crystals can be different from the structures of pure crystals of the corresponding metal. Metal salt crystals can be larger and/or have a decreased packing density and increased volumes for the same amount of metal atoms compared to pure metal crystals. The increased volume occupied by the metal salt can create mechanical stresses between the metal and the metal salt portions of the feature and between the metal salt and the dielectric material. Mechanical stresses can cause delamination of the previously adjacent layers of metal and dielectric material, and can lead to the formation of voids in the devices, and loss of device function and decreased device lifetime.

Metal salt formation in semiconductor devices can be caused by the movement of dopant materials from the dielectric to the metal. Two causes of salt formation, namely thermal cycling and electrical current flow, are described below.

### A. Dopant Diffusion with Thermal Cycling

Ideally, dopants are introduced into dielectric materials in such a fashion as to fix them relatively firmly within the matrix of the material. Dopants introduced by diffusion or implantation, however, are mobile during the doping steps, and a gradient exists of dopant concentration in the material, with the highest concentration of dopant present at the surface of the dielectric material from which the dopant was introduced. Correspondingly, the concentration of dopants deeper within the matrix of the dielectric material are, in general, lower than the concentration of dopants present at the surface. Because the surface of the dielectric material through which dopants are introduced can be in contact with a metal, there can be increased possibility that dopants will react with metals adjacent to the dielectric material, thereby forming metal salts.

The problem of dopant diffusion can be severe in situations in which subsequent thermal cycling steps are carried out. One reason for this can be that heating can free some of the dopants from the dielectric material that had been previously relatively fixed within the matrix. In modern semiconductor manufacture, numerous thermal cycles can be performed to create the complex, small devices. For example, deposition of metal layers can be carried out at temperatures in the range of about 430° C. to about 450° C. Tungsten can be deposited at a temperature of about 440° C., and titanium nitride (TiN) can be formed at a temperature of about 450° C. Alloys of metals can be formed at temperatures in the range of about 400° C. to about 450° C. Because fluorinated or doped glass can release fluoride ions and/or other dopant moieties upon heating to these temperatures, thermal cycling can cause progressively more fluorine to be available for diffusion out of the dielectric layer and into adjacent metal layers. Increasing the amount of fluorine and/or other dopants in the metal layer can lead to metal salt formation, increased mechanical stress at the interface, and delamination. With more numbers of heating cycles, the problem of interfacial stress and delamination can become increasingly severe.

### B. Dopant Diffusion with Electrical Current Flow

Metal salt formation can also have severe consequences in situations in which a finished semiconductor device feature is exposed to electrical currents during normal use. As electrical current passes through a semiconductor layer, the moving electrons can bombard static dopant atoms within the layer. If the static atom is deep inside a crystal of the semiconductor material, the atom has comparatively little freedom of movement, and will tend to remain within the crystal during electrical current flow.

For atoms at the edge of the crystal or grain (“grain boundary”) however, electrons striking the atom can dislodge the atom and cause it to migrate more easily than dopants deeper within the material. Because most doping methods provide higher concentrations of dopants near the surfaces of crystals, higher concentrations of relatively more mobile dopants can exist at grain boundaries. Moreover, for semiconductor materials having highly aligned, small crystals, the grain boundaries can be arranged so as to provide a relatively clear path or highway for the migration of dopant ions. As a dopant atom reaches the edge of one crystal, if another crystal's grain boundary is nearby, the atom can migrate to the adjacent crystal and can be carried farther away from its original location. Ultimately, the dopant atom can reach the edge of the semiconductor material. If the edge of the semiconductor material adjoins a metal, the dopant atom can react with the metal to form a metal salt. With continued progressive use, diffusion of dopants can become sufficiently severe as to create voids within the material or delamination of layers resulting in changes in the electrical properties of the semiconductor device.

### II. Monitoring of Metal Film Quality

In addition to problems associated with metal salt formation at interfaces, it can be important to provide means for accurately determining the thickness and quality of metal films being deposited on semiconductor substrates. Although there are methods for measuring the bulk properties of metal films, such as thickness and hardness, these methods may not be sufficiently suited for monitoring the quality of deposited films. Problems associated with metal film deposition can be especially difficult to overcome under conditions in which the grain interfaces and surface conditions of the film are sensitive to the particular deposition conditions. For example, the surface roughness of a metal film can vary widely depending on the flow rate of metal precursors, the temperature, the thickness of the film, the type of substrate, and other process variables. The problems associated with rough metal film surfaces can be especially difficult in very thin metal films, for example, less than about 200 Å. The problems can lead to poorly reproducible film thickness and poor electrical and/or mechanical properties.

### III. Monitoring of Silicide Film Deposition Quality

Similar problems to those encountered during metal film deposition also occur during silicidation of semiconductor features. It has been observed that during silicide formation, the surface of the silicide layer can undergo severe roughening. Surface roughening can lead to poorly reproducible electrical properties of the film, and uneven and unpredictable subsequent processing steps. The processing steps that can be adversely affected include depositions of dielectric materials, polysilicon layers and other semiconductor layers. Additionally, photolithographic procedures can become inaccurate when carried out on surfaces that are uneven. Finally, etching steps and ion implantation procedures can be inaccurate and unpredictable if the surfaces on which these processes occur are not even.

### IV. Calibration of Thermal Processing Equipment

Future semiconductor processing using copper and/or polymeric dielectric materials generally can be performed at temperatures lower than current processes using aluminum and/or glass. Because the temperatures can be in the range of about 250° C. to about 300° C., currently available methods for monitoring temperature are not well suited for the manufacture of future integrated circuits. Furthermore, even accurate monitoring of the temperature in the processing chamber may not reflect the true temperature at the processing site, for example the surface of the semiconductor device. This problem can be especially difficult to address in processing steps using rapid thermal processing, or “RTP.”

In RTP, the semiconductor device is exposed to infrared light or other source of electromagnetic radiation. The radiation is absorbed locally at the surface of the device, and thereby raises the temperature of the surface. Temperature can rise at the surface without a concurrent rise in the temperature of either the wafer as a whole or the chamber. Moreover, even accurate monitoring of the temperature of the back side of a wafer, for example, by the use of a thermocouple device, may not provide accurate, reliable information about the temperature at the crucial site, namely, the surface of the device.

### SUMMARY OF THE INVENTION

Thus, one object of this invention is to develop methods for decreasing the flow of dopants from dielectric materials to metal layers in semiconductor device manufacture.

Another object of this invention is to improve the adherence of dielectric layers to metal layers.

A further object of this invention is the development of methods for monitoring of metal film properties during deposition.

An additional object of this invention is the development of methods for monitoring the surface quality and film properties during silicidation steps.

A yet further object of this invention is the development of accurate methods for calibrating heating apparatus to improve the control and uniformity for surface temperatures of semiconductor wafers during processing.

An additional object of this invention is to manufacture semiconductor devices having improved electrical and mechanical performance, and increased device lifetimes.

Certain objects of this invention are met by the development of methods directed toward characterizing and regulating texture of semiconductor films. In one series of embodiments, this invention provides methods for decreasing the diffusion of fluorine and other dopants from dielectric layers into metal layers during semiconductor manufacturing and use. These results can be accomplished by providing a layer of metal nitride at the surface of the metal prior to the deposition thereon of a doped dielectric material. The subsequent deposition of doped dielectric materials can be performed to form structures in which the metal and dielectric materials can be separated from each other by a diffusion barrier. Further manufacturing steps including thermal cycling can be carried out, while inhibiting the diffusion of dopants from the dielectric material to the metal. Additionally, with use of the finished device, the barrier layer can decrease the electric flow-induced migration of dopants from the dielectric layer into the metal layer, thereby decreasing formation of metal salts. Decreasing the formation of metal salts at the metal-dielectric interface can improve electrical characteristics, decrease mechanical defects, and increase device lifetimes.

Therefore, in one aspect of this invention, the formation of a barrier layer of a metal nitride can be carried out using nitrogen rich plasma.

In another aspect of this invention, the metal nitride can be formed using nitrogen ion implantation.

In another aspect of this invention, the nitride can be formed using electromagnetic radiation.

Another aspect of this invention is the manufacture of semiconductor devices incorporating nitrided metal barrier layers between metal and dielectric materials.

In another aspect of this invention, semiconductor devices are provided incorporating nitrided metal barrier layers between metal and dielectric materials.

Other embodiments of this invention involve the monitoring of metal film deposition by measuring the sheet resistance as a function of the film thickness and deriving the power law relationship between those two variables. With thin films, if the film has large voids and/or areas of non-uniformity in the path of electrical current flow, then there is a larger opportunity for scattering of electrons, which can result in an increased sheet resistance. The relationship between electrical resistance and film thickness for films of certain quality do not necessarily follow a first power relationship, but rather can follow a fractal power law relationship. Methods are developed to take advantage of this discovery to more predictably produce thin metal semiconductor layers having better quality and more predictable, desired electrical properties.

In yet other aspects of this invention, the surface of semiconductor materials such as silicide films can be monitored in situ during deposition and/or annealing. By measuring the intensity and full-width at half maximum reflections of laser light, the sizes and distributions of surface features can be monitored. By selecting the wavelength and angles of incident light, the scattering properties can accurately provide information about the surface of the film. The processes of this invention can be used to monitor the deposition and subsequent processing of any material that undergoes a phase transition, including formation, crystallization, and annealing steps, in which a phase transition from crystalline structures to amorphous structures or alternatively, from amorphous structures to crystalline structures can occur.

Yet further aspects of this invention include new methods for monitoring and/or calibrating low temperature deposition apparatus using semiconductor wafers having thin layers of binary, ternary or other alloys that undergo phase transitions during heating to temperatures above certain thresholds. By the use of alloys having different phase transition temperatures, and by measuring the sheet resistance of surfaces comprising these alloys, the temperatures to which the surfaces are subjected can be accurately determined.

### BRIEF DESCRIPTION OF THE DRAWINGS

The invention will be described with respect to the particular embodiments thereof. Other objects, features, and advantages of the invention will become apparent with reference to the specification and drawings in which:

FIGS. 1a-1c depict a series of semiconductor devices of the prior art having a fluorinated dielectric material in direct contact with metal features.

FIG. 1a depicts a device of the prior art soon after manufacture.

FIG. 1b depicts a device as shown in FIG. 1a after a period of time had elapsed during which diffusion of fluoride to the metal/dielectric interface occurred.

FIG. 1c depicts a device as shown in FIGS. 1a and 1b after further diffusion of fluoride into the metal/dielectric interface, resulting in delamination.

FIGS. 2a-2b depict an embodiment of this invention for providing nitrided metal features.

FIG. 2a depicts an embodiment in which after formation of metal features, a layer of nitride is formed on the metal.

FIG. 2b depicts an embodiment as shown in FIG. 2a after formation of a layer of fluorinated dielectric material between the nitrided metal features.

FIGS. 3a-3g depict the manufacture and progressive delamination of a prior art semiconductor device having a fluorinated dielectric material between semiconductor device stacks comprising metals.

FIG. 3a depicts a prior art semiconductor device during manufacture, after deposition of several layers of semiconductor materials and a layer of photoresist.

FIG. 3b depicts a prior art semiconductor device as shown in FIG. 3a during manufacture, after photolysis of the photoresist layer.

FIG. 3c depicts a prior art semiconductor device as shown in FIGS. 3a-3b, after etching the metal layers and exposing an oxide layer.

FIG. 3d depicts a prior art device soon after manufacture, showing the metal stacks and the gap between the gaps being filled with a doped dielectric material.

FIG. 3e depicts a portion of a device as shown in FIGS. 3a-3d after a period of time during which diffusion of dopant to the metal/dielectric interface occurred.

FIG. 3f depicts a device as shown in FIGS. 3a-3b, after further diffusion of dopant into the metal/dielectric interface, resulting in formation of metal-dopant salts and delamination of the device locally at the interfaces between the un-nitrided metal and the doped dielectric material.

FIG. 3g depicts a device as shown in FIGS. 3a-3c after further dopant diffusion, metal/dopant salt formation and nearly complete delamination of the dielectric material from the metal stack.

FIG. 4 depicts an embodiment of this invention comprising a stack of metals, a nitrided metal barrier layer, and a fluorinated dielectric material.

FIG. 5 depicts an embodiment of this invention in which a localized area nitride is formed on a metal surface using electromagnetic radiation.

FIG. 6 depicts an embodiment of this invention in which a localized area of nitride are formed on a metal surface using nitrogen ion implantation.

FIG. 7 depicts a completed semiconductor device of this invention having nitrided metal layers.

FIGS. 8a-8b depict the surface of a semiconductor film having random and non-random domains, in which electrons can be scattered at the interfaces between the random and non-random domains. FIG. 8a depicts a situation in which relatively large non-random domains result in high electrical resistance.

FIG. 8b depicts a situation in which there are relatively smaller non-random domains than depicted in FIG. 8a above, resulting in lower electrical resistance than the film depicted in FIG. 8a.

FIG. 9 is a graph depicting the relationship between thickness and the power law of sheet resistance for a film having one texture.

FIG. 10 is a graph depicting the relationships between thickness and power law of sheet resistance for a series of films, each having a different texture.

FIG. 11 is a drawing depicting the surface of a silicide film having surface islands or beads.

FIGS. 12a-12d are drawings depicting an embodiment of the invention and showing a semiconductor surface having beads and a fixed angle laser system for monitoring the scattering caused by roughness.

FIG. 12a depicts the surface of a film having relatively small surface beads and a laser light source and detector.

FIG. 12b depicts the results of a study of the intensity of laser light detected as a function of the temperature of the silicide film depicted in FIG. 12a.

FIG. 12c depicts the surface of a film having relatively larger surface beads compared to those shown in FIG. 12a.

FIG. 12d depicts the results of a study of the intensity of laser light detected as a function of the temperature of the film shown in FIG. 12c.

FIG. 13a-13d are drawings depicting another embodiment of this invention showing a semiconductor wafer having a surface film and a mobile laser light source and detector.

FIG. 13a depicts a film having relatively small surface beads.

FIG. 13b illustrates the relationship between the intensity of reflected light plotted as a function of the reciprocal of the wavelength for film having relatively large beads. The peak intensity is related to the average bead size.

FIG. 13c depicts a film having relatively larger beads than those depicted in FIG. 13a.

FIG. 13d illustrates the relationship between the intensity of reflected light plotted as a function of the reciprocal of the wavelength for a silicide film having relatively larger beads that those of FIGS. 13a and 13b. The peak intensity is shifted to the left, because of the relatively larger bead sizes in the film of FIG. 13c.

FIG. 14a is a drawing depicting an embodiment of this invention in which a layer of a binary alloy has been deposited on the surface of a silicon wafer and a sheet resistance probe system is disposed above the surface at one area of the surface.

FIG. 14b is a drawing depicting the relationship between sheet resistance and temperature of a layer of binary allow during an annealing step.

### DETAILED DESCRIPTION

This invention addresses problems of the prior art by providing methods for characterizing texture of semiconductor materials and for alleviating problems associated with texture. The term “texture” is descriptive of the grain, crystal, or amorphous material and void structure of a semiconductor material. Many useful semi-conductor materials comprise crystalline materials, wherein the atoms and molecules are relatively ordered. Crystals can have sizes ranging from the nanometer range to the micron range. Crystals can be packed in ordered arrays or an be packed randomly. Between crystals, areas of non-crystalline, random, or amorphous materials or even voids can be present. The size and orientation of crystals and the relative amounts and locations of amorphous regions and/or voids all can contribute to overall texture.

Certain aspects of texture are significant to this invention. Specifically, grain boundaries can be important in affecting the movement of electrons, atoms and/or ions at metal-dielectric interfaces. The relationship of void regions to non-void regions in conductors can be important to electrical current flow. Additionally, the roughness of surface as a result of texture can be important to the detection of film surface properties, phase transitions, and subsequent manufacturing processes.

### I. Nitrided Metal Layers

Certain embodiments of this invention can mitigate some adverse effects of texture of insulating elements, such as oxides. These embodiments comprise the manufacture of diffusion barriers to inhibit the diffusion of dopants from doped semiconductor materials into metal features. By decreasing the diffusion of dopants into the metal, the formation of metal salts can be diminished, thereby decreasing the mechanical stresses to which device layers are subjected. Decreasing mechanical stresses can decrease the delamination of semiconductor materials from each other, and thereby can improve electrical efficiency and useful lifetime of semiconductor devices.

The diffusion barrier layers of this invention can be metal nitrides, oxynitrides, or other type of barrier layer known in the art to decrease dopant diffusion and is compatible with the metals, the dielectric materials and the methods used. Although the descriptions that follow are directed toward formation of barrier layers of nitrided metal, the scope of this invention is not limited to nitrides and oxynitrides.

To manufacture metal nitrides of certain embodiments of this invention, it can be advantageous to provide sufficient nitrogen into the metal to reach a depth of from about 10 Å to about 1000 Å. In alternative embodiments, the depth of the nitrogen can be in the range of about 50 Å to about 350 Å, and in another embodiment, about 100 Å. We have found that compared to non-nitrided metals, metal nitrides having thicknesses in this range can be relatively impermeable to dopant materials.

The nitride can be manufactured in any convenient fashion. In certain embodiments, the metal nitride can be formed using a nitrogen-rich radiofrequency plasma, wherein the semiconductor device is subjected to a forming gas, such as a combination of nitrogen and hydrogen gases. In other embodiments, the metal nitride can be formed using electromagnetic radiation to locally form the metal nitride, and in alternative embodiments, metal nitrides can be formed using nitrogen ion implantation. These methods are generally known in the art, and application of them to this invention are described further below.

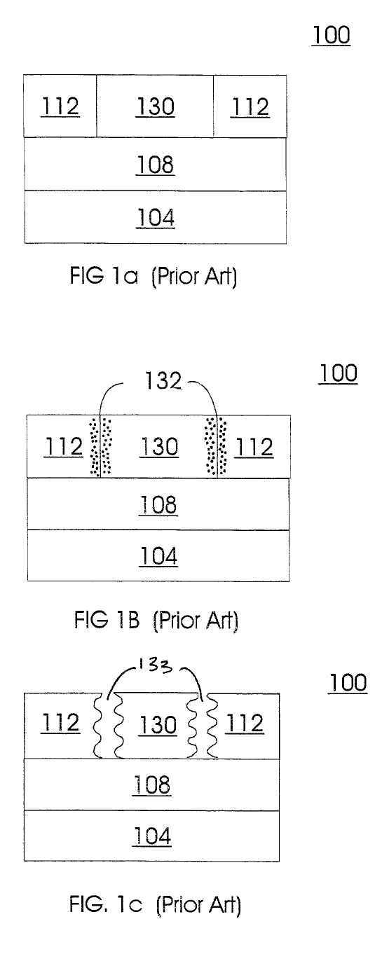

Advantages of embodiments of this invention are described with reference to conventional methods of manufacturing semiconductor devices. FIGS. 1a-1c depict prior art semiconductor device 100 after manufacture and during progressive metal salt formation and delamination. FIG. 1a depicts a prior art device 100 soon after manufacture, having a silicon substrate 104, an oxide layer 108 typically comprising SiO₂, conductive metal features 112 and a region of dielectric material 130, for example, a fluorinated dielectric material, between conductive metal features 112.

FIG. 1b depicts a prior art device as shown in FIG. 1a after diffusion of fluorine moieties into the metal layer had begun. Region 132, here shown stippled, represents areas in which metal salts were formed. At this stage, delamination had not become severe.

FIG. 1c depicts a prior art device as shown in FIGS. 1a and 1b after additional thermal processing. Regions 133 between metal features 112 and dielectric material 130 have widened, resulting in delamination of the metal and dielectric materials.

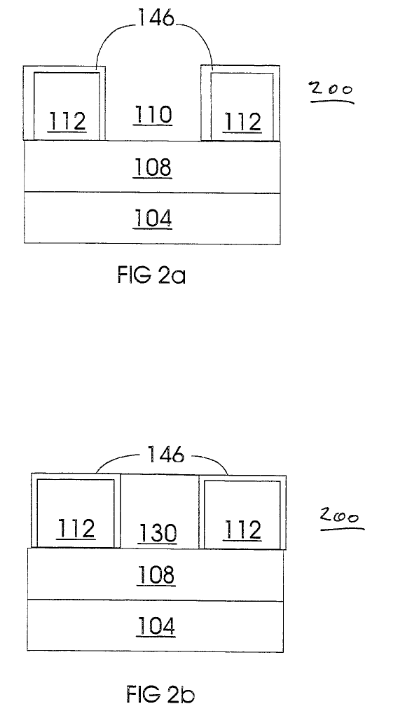

FIGS. 2a and 2b depict one aspect of this invention. FIG. 2a depicts a semiconductor device 200 having a silicon substrate 104, a layer of oxide 108, typically SiO₂, two metal features 112 separated by a gap 110. Layers 146 of metal nitride have been formed on metal features 112. FIG. 2b depicts a semiconductor device 200 as shown in FIG. 2a after filling gap 110 with fluorinated dielectric material 130.

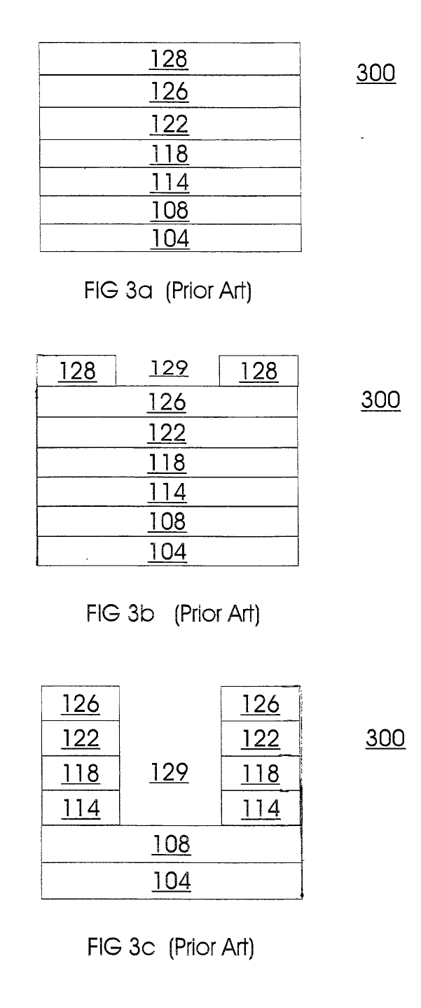

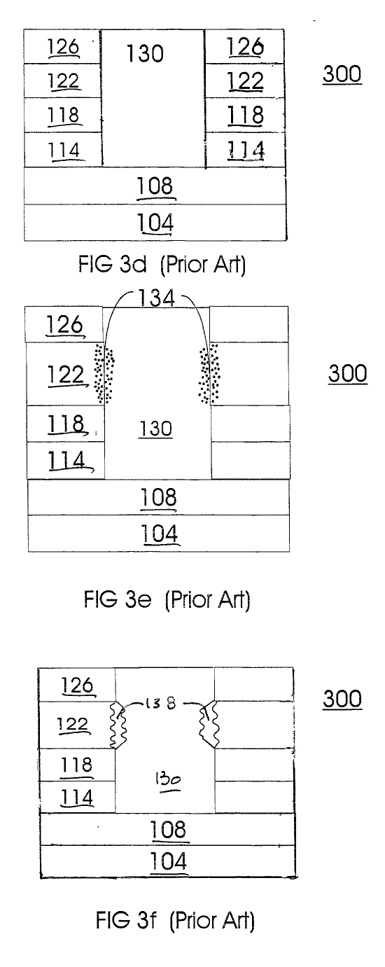

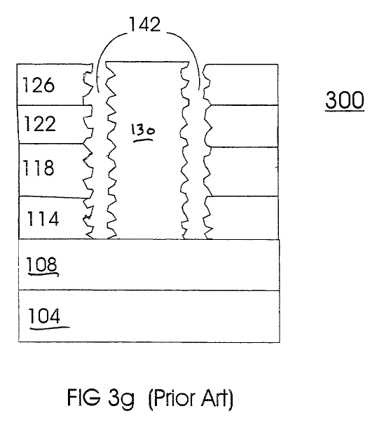

FIGS. 3a-3g depict the manufacture of and progressive delamination of another prior art semiconductor device having semiconductor stacks with several metal layers.

FIG. 3a depicts a portion of a prior art semiconductor device 300 during manufacturing. The device has a substrate 104, an oxide layer 108, a layer of titanium (“Ti”) 114, a layer of titanium nitride (“TiN”) 118, a layer of aluminum (“Al”) 122, a layer of titanium nitride 126, and a layer of photoresist (“PR”) 128 on the top surface of device 300.

FIG. 3b depicts a portion of a prior art semiconductor device 300 as shown in FIG. 3a after masking and photoresist lithography to produce channel 129, thereby exposing TiN layer 126.

FIG. 3c depicts a portion of a prior art semiconductor device 300 as shown in FIG. 3b after etching the TiN layer 126, Al layer 122, TiN layer 118, and Ti layer 114, thereby revealing oxide layer 108. Channel 129 represents the location for subsequent deposition of dielectric material. shown in FIGS. 3a-3c, after deposition of fluorinated dielectric material 130, but before subsequent processing steps had been carried out. The fluorinated dielectric material 130 is shown completely filling the area of FIG. 3b that was channel 129. FIG. 3e depicts a portion of a prior art semiconductor device 300 as shown in FIGS. 3a-3d after subsequent processing involving thermal cycling has caused fluorine moieties to diffuse from dielectric material 130 to aluminum layers 122, forming areas 134 of metal salt formation, herein shown stippled.

FIG. 3f depicts a portion of a prior art semiconductor device 300 as shown in FIGS. 3a-3e after further salt formation and delamination, where the dielectric material 130 and aluminum layers 122 are separated by gaps 138.

FIG. 3g depicts a portion of a prior art semiconductor device 300 as shown in FIG. 3a-3f after further metal salt formation and progressive delamination. Dielectric material 130 has separated from Ti layer 114, TiN layer 118, aluminum layer 122 and TiN layer 126, thereby forming gaps 142.

### A. Formation of Semiconductor Materials Having Improved Texture

It can be desirable to provide semiconductor materials that have comparatively low dopant mobility and are relatively void-free. Materials having low dopant mobility and low amounts of voids have good texture. Good texture can be achieved by providing relatively large crystals or “grains” of the material. Large grains have relatively lower surface area to volume ratios than do small grains, and therefore larger grains provide fewer grain boundaries and therefore fewer pathways for dopant migration, either by chemical diffusion or by electron bombardment.

In certain embodiments of this invention, the metal materials can be deposited in fashions to provide good texture. Aluminum can form fiber texture made up of “face center cubic” (“FCC”) crystals having a 1:1:1 orientation, that is, cubic crystals wherein the basal plane of the fiber is defined by the triangle formed by lines connecting comers of three adjacent sides of the cubic crystal. When FCC crystals grow on oxide, the fiber bases can have a random orientation on the oxide. Compared to the crystal structure of Ti described below, random orientation of FCC Al crystals provides relatively less direct contact between adjoining faces of adjacent crystals, and provides for relatively more spaces or gaps between nearby crystals. Because Al FCC crystals grow as fibers, there can be comparatively long grain boundaries, or “highways” in the direction perpendicular to the plane of the underlying layer. Highways can provide paths by which dopants reaching the surface of the Al layer can migrate along the Al fiber and thereby contaminate the metal layer.

In contrast with aluminum FCC fibers, titanium forms hexagonal close pack (“HCP”) crystals. Hexagonal close pack crystals, in cross-section, have hexagonal shape, and the hexagons of adjacent crystals can have sides that are in close apposition to each other, thereby forming a regular array of hexagons with comparatively little space between the crystals. Subsequently deposited layers of HCP crystals can be formed on the top surface of a previously deposited layer of HCP crystals. However, the hexagonal array of a second layer does not necessarily form directly in alignment with the hexagonal crystal array of the underlying layer. That is, each subsequent layer of HCP crystals can have an offset from the layers above and below. As a result of this structure, the grain boundaries are less continuous in the perpendicular direction, compared to fiber texture of Al.

In embodiments comprising Al deposited on Ti deposited on oxide, the interface between the aluminum and titanium can be the site of formation of titanium aluminide (TiAl₃). TiAl₃ has a smaller unit cell than either Ti or Al alone, and the formation of TiAl₃ can create stress voids in the interface, resulting in poor texture. Therefore, in an embodiment of this invention to provide semiconductor materials having good texture, a layer of titanium nitride (TiN) can be deposited on the Ti layer before the deposition of the Al layer. Subsequent deposition of Al can be carried out, which can decrease the formation of TiAl₃ and the formation of stress voids, and therefore can result in a semiconductor stack having improved texture.

Similarly, the quality of structure of other semiconductor materials can have significant influence on their electrical and physical properties. By providing good texture to silicide and/or other films, subsequent processing steps and performance can be improved.

### B. Formation of Nitrided Metal Using Nitrogen-Rich Plasmas

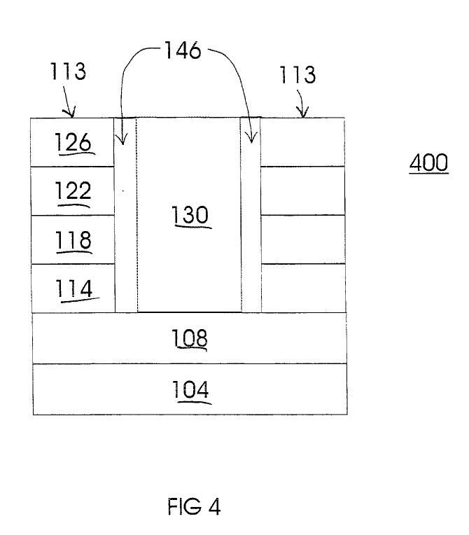

According to one group of embodiments of this invention, by way of example only, see FIG. 4 below, the nitrided metal can be formed by exposing an etched channel to a nitrogen-rich plasma generated in a radiofrequency (“rf”) plasma deposition chamber. The nitrogen rich plasma can be created using a plasma forming gas comprising nitrogen and hydrogen gases. The ratio of H₂ to N₂ can be in the range of about 0.1:1 to about 4:1, alternatively in the range of about 0.5:1 to about 2:1, in another embodiment, about 1:1, and in yet another embodiment, about 3:2. If the nitrogen concentration is too low, the nitrogen ions might not attain sufficient thermal energy to penetrate into the dielectric material, thus resulting in a layer of metal nitride that does not have the desired thickness. By providing hydrogen and nitrogen gases together in the above ranges, the thickness of the metal nitride can be sufficiently large to produce the desired decreased diffusion of dopants into the metal.

In other embodiments, metal oxynitrides can be formed using plasmas by adding O_{2,} N₂O and/or NH₃ to the H₂ forming gas mixture. By selecting different ratios of NH₃ to O₂ or N₂O in the forming gas, different ratios and stoichiometries of nitride and oxynitride can be manufactured to provide barrier layers having desired thicknesses and abilities to inhibit dopant diffusion.

In general, the rf plasma power can be in the range of about 100 Watts to about 1000 Watts. In other embodiments, the power can be in the range of about 400 Watts to about 800 Watts, and in another embodiment, to form titanium nitride, a power of about 750 Watts can be desirable.

If desired, the reactive components of the forming gas can be carried in an inert carrier, such as a noble gas, including xenon, krypton, argon, neon, or helium. In general, using noble carrier gases having higher atomic weights can be desirable in that they can impart sufficient thermal energy to the forming gases to create a desired plasma density at a relatively low power. Using noble gases having lower atomic weights can require higher powers to create a sufficiently dense plasma. Thus, the use of helium can require the highest power to generate an effective plasma, whereas argon can be used to create an effective plasma at power in the range of about 400 Watts to about 500 Watts. Moreover, using xenon can provide effective plasmas at even lower power settings than are required for argon. It can be desirable to select low power settings because if the power is too high, the metals, especially titanium and titanium nitride can become brittle.

The pressure in the plasma chamber can be in the range of about 100 milliTorr to about 50 Torr. Alternatively, the pressure can be in the range of about 1 Torr to about 10 Torr, and in another embodiment, about 1.3 Torr for forming metal nitrides and about 4 Torr for forming nitrides on dielectric materials.

The time required to form metal nitrides is generally in the range of about 5 seconds to about 1 minute. These times can correspond to formation of metal nitride layers having thicknesses of about 10 Å to about 1000 Å, respectively. However, the specific power, pressure and time can be selected to accommodate particular needs.

The thickness of the metal nitride layers of embodiments of this invention can have thicknesses in the range of about 10 Å to about 1000 Å, alternatively in the range of about 50 Å to about 350 Å, and in another embodiment, about 100 Å. The thickness can be chosen depending on the dimensions of the metal feature to be protected. For wide metal features having about 5000 Å dimensions, a metal nitride having a thickness of about 1000 Å can be desired, and can inhibit dopant diffusion more effectively than thinner layers. Metal nitrides of about 1000 Å can provide for about 3000 Å of non-nitrided metal to remain, thereby providing satisfactory current flow without causing undesirably large resistance. Alternatively, for metal features having dimension of about 3500 Å, it can be desirable to provide a metal nitride having a thickness of about 500 Å on each side of the metal structure. In this situation, the total thickness of the metal nitride could be about 1000 Å, thus leaving about 2500 Å of metal for conduction. In future embodiments, in which the metal features can be as narrow as about 1000 Å, it can be desired to provide metal nitride layers having thicknesses of about 100 Å. The remaining metal can therefore have a thickness of about 800 Å, which can be sufficient for future integrated circuits.

One advantage of using nitrogen-rich plasmas is that metal nitride formation can occur at wafer temperatures well below those of the plasma. By keeping the wafer relatively cool, implanted nitrogen can be less likely to diffuse away from the matrix of the metal, and therefore can have greater time to form chemical bonds with the metal. However, if the wafer is too cool, the rates of metal nitride formation can be undesirably low. We have found that maintaining the wafer on a chuck having a temperature of between about 200° C. to about 450° C., or alternatively about 400° C. can provide a desirable combination of metal nitride reaction rates and stability of the metal nitride once formed.

FIG. 4 depicts a portion of a semiconductor device 400 of an embodiment of this invention wherein an aluminum nitride (AlN) layer 146 is formed on the sidewalls of stacks 113 before deposition of dielectric materials. Stacks 113 comprise layers of Ti 114, TiN 118, Al 122, and TiN 126. Titanium layer 114 can have a thickness in the range of about 100 Å to about 250 Å. If the Ti layer is too thin, then “oxide defects” can be carried over from the oxide layer 108 to the overlying TiN layer 114 and Al layer 112. Titanium nitride layer 118 can have a thickness in the range of about 200 Å to about 800 Å. Aluminum layer 122 can generally have a thickness in the range of about 3000 Å to about 2 μm. Titanium nitride layer 126 can act as an anti-reflective layer, which can permit the more accurate photolysis of an overlying photoresist layer (not shown). Titanium nitride layer 126 can generally have a thickness of from about 250 Å to about 1500Å. Nitride layer 146 is formed prior to deposition of fluorine-doped dielectric material 130.

In alternative embodiments, Ti layer 114 of FIG. 4 can be replaced by aluminum:tantalum (Al:Ta) in a ratio of about 50:50 by weight. Al:Ta can have a good texture. “Good texture” in this context means that in X-ray diffraction analyses of crystal structures, at least about 90% of the total intensity of the diffraction pattern lies within about 2°, and where the crystal orientation is 1:1:1. Crystals having the above properties exhibit longer useful lifetimes.

The effectiveness of an AlN layer to act as a barrier to dopant diffusion can be related to the depth into the Al layer the nitrogen rich plasma can deposit nitrogen radicals and thereby form nitrided metal. At the surface of the aluminum layer, the amount of AlN is maximal, and depends on the conditions of nitride formation. Farther into the metal layer, progressively less AlN is formed, so that by about 400 Å into the metal crystal, sufficiently little AlN is present to act as an effective barrier.

In prior art devices not having AlN layers, and in which the fluorine content in the bulk dielectric materials is about 6% to about 7%, fluorine can diffuse out of the dielectric layer and into the metal. Thus, near the surface of the dielectric layer, the fluorine concentration can be as low as about 1%. The gain of fluorine by a nearby metal layer, can lead to the problems associated with metal/fluoride salt formation.

In contrast, for devices having AlN layers of embodiments of this invention, there can be comparatively less decrease in fluorine concentration from the dielectric material, and therefore less fluorine can diffuse into the metal layer. As a result, less metal salt can form, and the problems associated with metal salt formation can be decreased.

### C. Electromagnetic Radiation to Form Metal Nitride

Other embodiments of this invention can provide for electromagnetic radiation (“EMR”) to form barrier layers locally at desired sites within a semiconductor device. Methods for generation of electromagnetic radiation and the formation of nitride using these methods is within the skill in the art and will not be described further. FIG. 5 depicts such an embodiment 500. A portion of a semiconductor device 500 has a substrate 104 and layers of oxide 108, titanium 114, titanium nitride 118, aluminum 122 and titanium nitride 126 deposited thereon. After formation of a channel 129 as in FIG. 3c, a beam of electromagnetic radiation (“EMR”) is directed downward and laterally (arrow) in channel 129 so as to generate a layer of aluminum nitride locally on aluminum layer 122. Subsequently or concurrently, a beam of EMR is directed at the opposite sidewall to form a layer of aluminum nitride on that sidewall of channel 129. After forming the aluminum nitride layers, channel 129 can be filled with a doped dielectric material.

### D. Ion Beam Implantation to form Metal Nitride

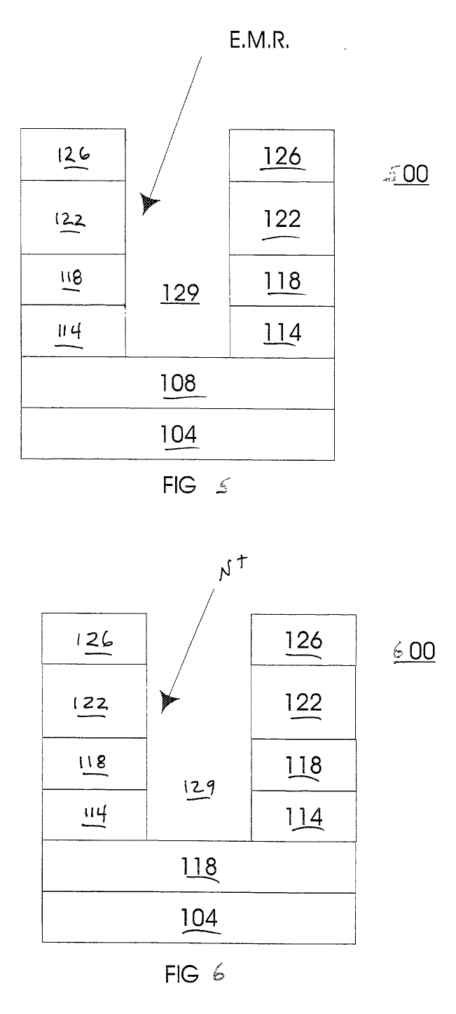

In alternative embodiments of this invention, instead of using EMR, a barrier layer can be manufactured by implanting nitrogen ions locally into the metal region to form a metal nitride. FIG. 6 depicts an embodiment of the invention, similar to that depicted in FIG. 5, except that a focused beam of nitrogen ions (“N+”) is directed (arrow) toward the sidewall having the metal layer 122. A beam can also be directed at the opposite side of channel 129, thereby providing a barrier layer at that location. The generation of ion beams are carried out by methods that are known in the art, and will not be described further.

### E. Subsequent Manufacturing Of Semiconductor Devices

After the formation of the barrier layer, doped or undoped dielectric materials can be deposited. The dielectric material can be silicon dioxide, doped with fluorine in sufficient concentration to produce about 3% to about 10%, alternatively about 5% fluorinated silicate glass (“FSG”) Alternatively, any fluorine-containing dielectric material can be used. It can also be desirable to provide a metal interface with a dielectric material that is doped with phosphorous or boron. Examples include phosphorous doped silicate glass (“PSG”)boron doped silicate glass (“BSG”) and borophosphorous silicate glass (“BPSG”). These materials can be manufactured using methods known in the art. Other examples of suitable dielectric materials include polyfluoroethylene “PFTE” or other fluorinated low dielectric constant polymers.

To complete a semiconductor device, subsequent steps can include deposition of metal layers, metal masks, etching, interlayer dielectric deposition and polishing, contact etching, barrier metal deposition, tungsten plug formation tungsten polishing, and other steps known in the art.

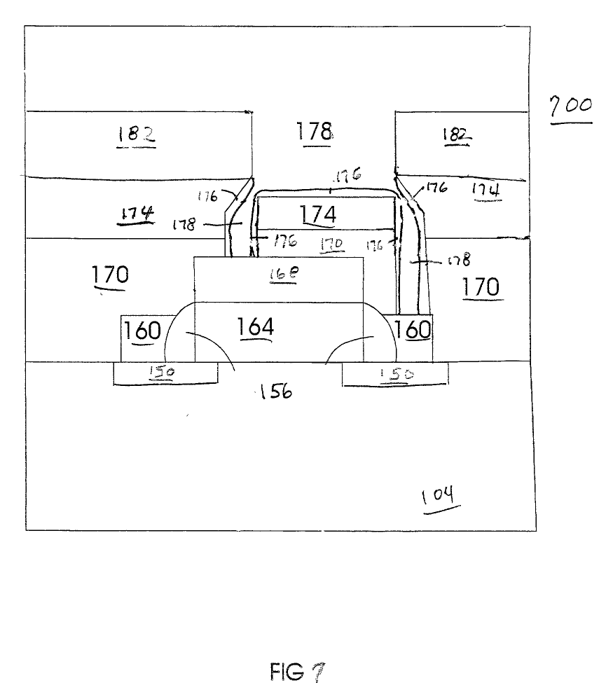

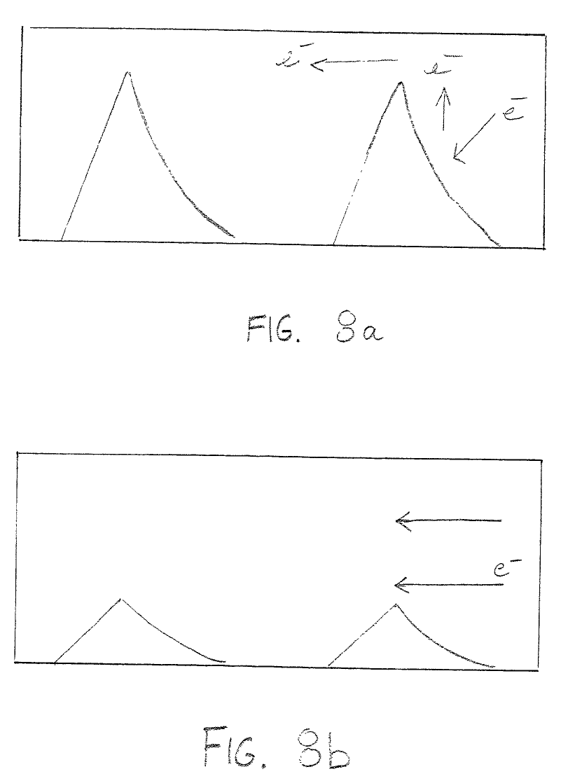

An example of a semiconductor device 700 is depicted in FIG. 7. Substrate 104 has source and drain regions 150, sidewall spacers 156 on either side of gate 164, silicide regions 160 on either side of sidewall spacers 156 and another silicide layer 168 over gate 164. Oxide layer 170 covers at least a portion of substrate 104, source and drain regions 150, and silicide layers 160 and 168. Interlevel dielectric (ILD) 174 overlies oxide layers 170, and a layer of titanium 182 overlies ILD layer 174. Barrier layers of nitride 176 line vias which are to be filled with conductive metal. Barrier layers 176 are formed on the oxide layers 170 and 174. The barrier layer-lined vias are filled with tungsten 178 which connects to silicide layer 160 and silicide layer 168, and additional tungsten 178 overlies the titanium layer 182.

### II. Monitoring Metal Film Deposition

To monitor deposition of thin metal films of this invention, novel applications are provided of a newly discovered relationship between sheet resistance (“Rₛₕ”) of a thin metal film having a certain film texture, and the thickness of that film. Sheet resistance can be measured using methods known in the art, and some are described below in section IV.

For relatively thick metal films, having thicknesses in the range of about 350 Å or greater, the sheet resistance as a function of the film thickness is predicted by the Drude model, in which the sheet resistance is proportional to the reciprocal to the first power of the film thickness. This relationship holds for aluminum films that have good grain structure.

However, for thin films having thicknesses in the range of about 100 Å to about 200 Å, the relationship between sheet resistance and film thickness does not obey a first-power Drude model. Rather, the relationship between sheet resistance and film thickness can have a fractal power, for example, of about −1.3 instead of −1. Variations in the roughening of the interface between the film and the underlying material can result in deviations of the power function from −1.

When formed, metal film interfaces can have different textures depending on the type of metal used. The texture of an interface can depend on the crystalline structure of the metal. For example, titanium films form as hexagonal close pack (HCP) crystals on the substrate surface. With further deposition of titanium, subsequent layers of HCP crystals can be offset from the lower crystal layers. Therefore, as Ti grains grow, the subsequently deposited layers can occupy greater area, thus causing the grains to take on an irregular shape. When the grains grow sufficiently to meet one another on the surface, there can be areas of random phase material or voids between the grains. Thus, Ti films can have higher void density at the interface between the film and the underlying film than in areas near the surface of the metal film. The higher void density near the interface can mean that with further deposition of relatively void-free Ti above the grain intersections, thicker films can have larger areas without voids. Thus, as the film thickness increases, the contribution of voids to sheet resistance decreases, and if the film thickness is sufficiently large, e.g., greater than about 350 Å, the relationship of sheet resistance to reciprocal of the thickness follows the Drude model, in which the relationship has a power of about −1.

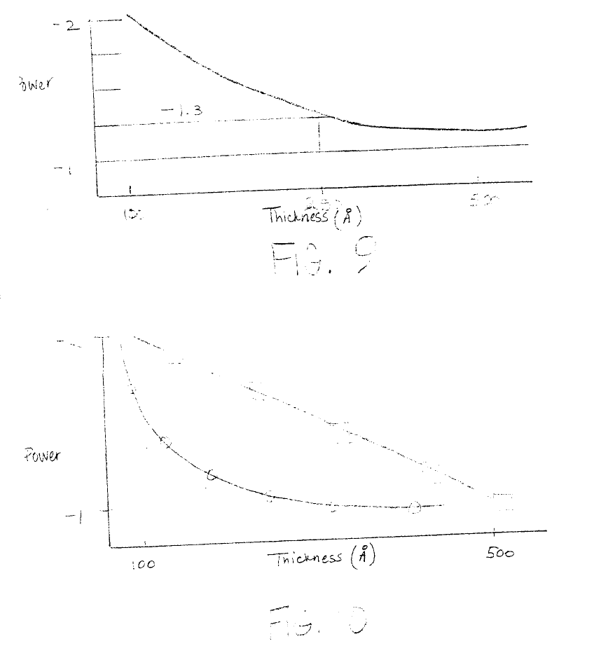

To illustrate a possible mechanism for the observed effect of thickness to electrical sheet resistance, refer to FIGS. 8a and 8b. FIGS. 8a and 8b depict films having high resistance (FIG. 8a) and low resistance (FIG. 8b), respectively. In FIG. 8a, a film having relatively large areas of material having random phases or voids is shown. As depicted, there are areas of minimum cross-section of the non-random portion of the film. Electrical resistance is lower in areas without large areas of random phase or voids. In contrast, electrical current can be deflected by the random phase or void regions during passage in a direction parallel to the film surface. Electrons (“e−”) that strike the boundaries of the random phase or voids, and can be deflected away from the parallel flow, thus distorting the flow of electrical current in the film. This distortion of current flow can be reflected in increased sheet resistance. For very thin films, because the relative proportions of areas containing voids or random phase to areas having good texture is increased, the mean time that an average electron travels before encountering a void or area of random phases can decrease. Therefore, the frequency of scattering events in the film increases. However, this is one possible mechanism, and this invention is not intended to be limited to any particular theory for operability.

In contrast, FIG. 8b depicts a film having relatively smaller random phase or void regions. The small void regions means that there is a larger proportion of the film's thickness that is free of voids or random phase regions, and therefore, there is decreased likelihood that an electron flowing parallel to the surface will be deflected. The mean time between scattering events can therefore be larger for these films than those with large grains or increased void density. Therefore, there can be decreased tendency to distort the flow of electrons, a situation that can be manifested as a lowered sheet resistance.

In contrast to Ti films, aluminum films can exhibit less dependence of sheet resistance on film textures. This can be due to the tendency of aluminum deposited by vapor phase deposition to form fibers with a face cubic center (FCC) structure. This type of crystalline structure promotes the formation of a fiber texture orientation being generally perpendicular to the surface on which the fibers form. This type of crystalline structure can result in less variation in void density with film thickness than in the case for HCP crystals, exemplified by Ti. However, because adjacent aluminum fibers tend to form independently of one another, relatively large voids can form between the fibers. Because there is little difference in void density throughout the film thickness, the relationship between sheet resistance and film thickness for Aluminum does not deviate as greatly from the Drude model as do to films of titanium or other materials having HCP crystalline structure.

Titanium and aluminum are described herein as examples of different types of crystalline materials. The methods of this invention can be applied to materials having any type of texture, and the scope of this invention is not intended to be limited to the above two specific examples.

Thus, for any given film type and texture, the sheet resistance will be inversely related to a power of the film thickness. By studying various types of films having various textures, using independent measurements of film thickness, e.g., optical interference methods, and the knowledge of the power law relationships between thickness, texture and sheet resistance, measurements of sheet resistance can be related directly to the film thickness. Thus, with knowledge of the deposition conditions and the power law relationships, the film thickness can be easily determined using measurements of sheet resistance.

The relationship between film thickness and the power law for a film having a single texture is illustrated by FIG. 9. The horizontal axis represents the thickness in Å of a film of a semiconductor material, and the vertical axis represents the power of the relationship between film thickness and sheet resistance. As depicted for this example, on the right side of the figure, representing film thicknesses greater than about 350 Å, the power law relationship is 1. However, for films thinner than about 350 Å, the power law relationship varies from −1, and increases progressively as the film thickness decreases.

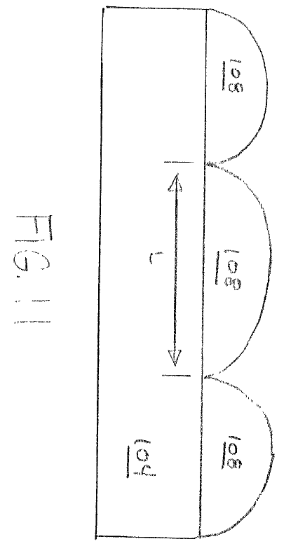

FIG. 10 illustrates the relationships between film thickness and the power law relationships for films having different textures. For a desired film material there will be a family of curves describing the relationships between film thickness and the power law relationship for different textures. To take advantage of this information, a manufacturer can first select a material to be deposited, then can select a desired texture and film thickness. Then, by referring to such a family of curves as depicted in FIG. 10, the manufacturer can choose the process conditions to achieve that desired texture and film thickness. Alternatively, one can choose a desired film thickness and then select process conditions that will permit the formation of a film having acceptable texture.

III. Monitoring of Changes in Surface Texture

Other embodiments of this invention relate to methods for monitoring texture and/or changes in surface texture of materials during semiconductor manufacture. Vapor phase deposition of semiconductor materials typically can occur in focal areas, herein termed “nucleation sites.” As deposition begins, atoms or particles from the vapor phase can interact with the surface, and chemical bonds can form, or alternatively, molecules adsorbing to the surface can become oriented in particular ways. As films grow, new atoms can be added to the film, causing the film to grow laterally over the surface and/or vertically, to increase in thickness. These processes can be monitored using aspects of this invention. Additionally, subsequent processing steps, including annealing can be monitored closely to minimize problems associated with excessive heating of semiconductor materials.

Examples of film materials having surface texture whose characterization is of importance to the semiconductor industry include the suicides. However, the principles and methods described herein for silicide formation can also be applied to a large variety of other materials having surface textures. Thus, these aspects of this invention are not intended to bel limited in their application to any particular type of material.

### A. Formation of Silicides

Silicide formation involves the addition of metal atoms to a silicon surface and subsequent chemical reactions to produce suicides. For example, titanium silicide, TiSi₂ or cobalt silicide, CoSi₂ can be formed from nucleation sites on the silicon surface. The formation of nucleation sites is dependent on temperature, with more sites being formed at low temperatures. Once a nucleation site has been formed, the silicide reaction tends to occur at the interface between the existing silicide and the adjacent silicon. Because the metal silicide occupies a larger volume than the pure silicon, the silicide forms “beads” or “islands” being raised above plane of the silicon the surface. The growth of silicide islands or beads progresses from the nucleation site outwards; as silicide growth continues, the beads become thicker and wider, covering more area, until the edges of the beads meet and the silicide layer completely covers the silicon substrate. However, when the beads begin to merge, the surface is “lumpy,” being thicker near the center of the beads, and thinner toward the edges. As further silicide formation occurs, growth occurs primarily in the valleys or depressions at the edges of the beads. When the valleys are progressively filled in, the overall uniformity of the silicide layer can improve.

The growth rate of a silicide layer is higher at higher temperatures, and is lower at lower temperatures. Thus, in certain aspects of this invention, it can be desirable to begin the silicidation process at a low temperature, to generate a relatively high number of nucleation sites, and then, once a sufficient number of nucleation sites are formed, to then increase the temperature to increase the growth rate and thereby decrease the time needed to perform the silicidation procedure. Moreover, if more nucleation sites are provided, the beads can coalesce to completely cover the surface sooner than if fewer nucleation sites are provided. With more nucleation sites, the thickness of the beads can be less than for beads grown from fewer nucleation sites. Therefore, the overall uniformity of the film can be improved. Unfortunately, if growth rates are too high, the process can result in increased surface roughness. To prevent this problem, it can therefore be desirable to monitor the surface texture of a film during deposition.

### B. Monitoring of Silicide Formation

Monitoring of silicide or other deposited films can be carried out by measuring light scattering by the surface of the layer as it grows. In certain embodiments of this invention, the measurement of light scattering can be accomplished using a laser light source directing abeam of light at an angle to the surface and measuring the scattering of the reflected light. The intensity of scattered light at a given angle and wavelength exhibits a scattering profile having a characteristic maximum and full width at half-maximum that can depend on the average size of the features responsible for the surface roughness of the film. Because scattering is a surface phenomenon, it can be used to monitor the changes in surfaces in real time during film deposition or annealing.

In one series of embodiments of this aspect of the invention, the wavelength of incident light is selected to match the critical feature size on the surface to be monitored. The wavelength of light can be in the infrared, visible, ultraviolet range. The wavelength, λ of light is related to the wavenumber Xo, according to the following formula:

$$λ = \frac{1}{Xo} .$$

Also, the wavelength is related to the wavenumber by the following formula:

$$\frac{2 π}{Xo} = λ .$$

The size of the structures detected using incident laser light are dependent on the wavelength of light used. For example, titanium silicide, TiSiO₂, has feature sizes that can be in the range of about 4000 Å in width, wavelengths of light below about 4000 Å can be made to detect changes in surface feature size. FIG. 11 illustrates a film of silicon (Si) having bumps of Ti/SiO₂ having an average length L.

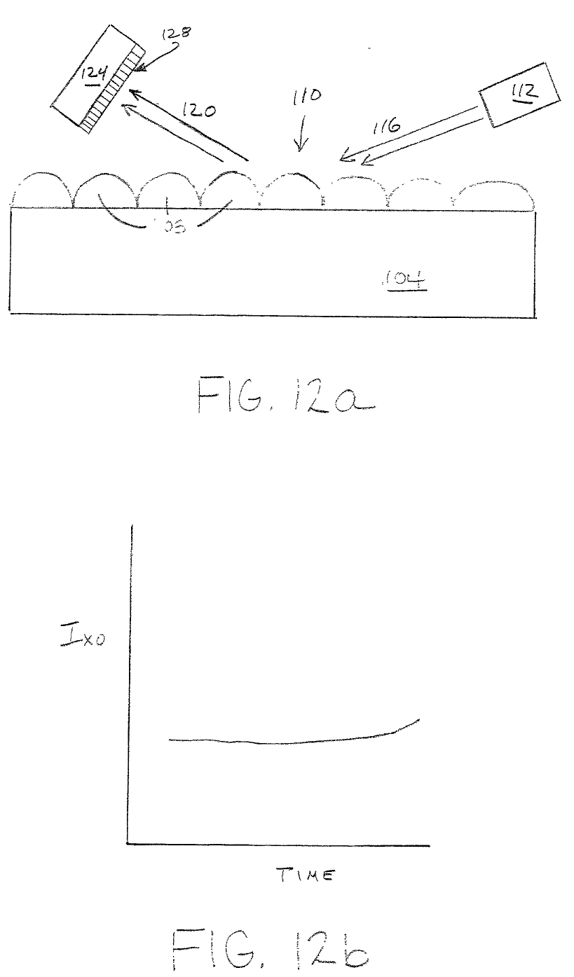

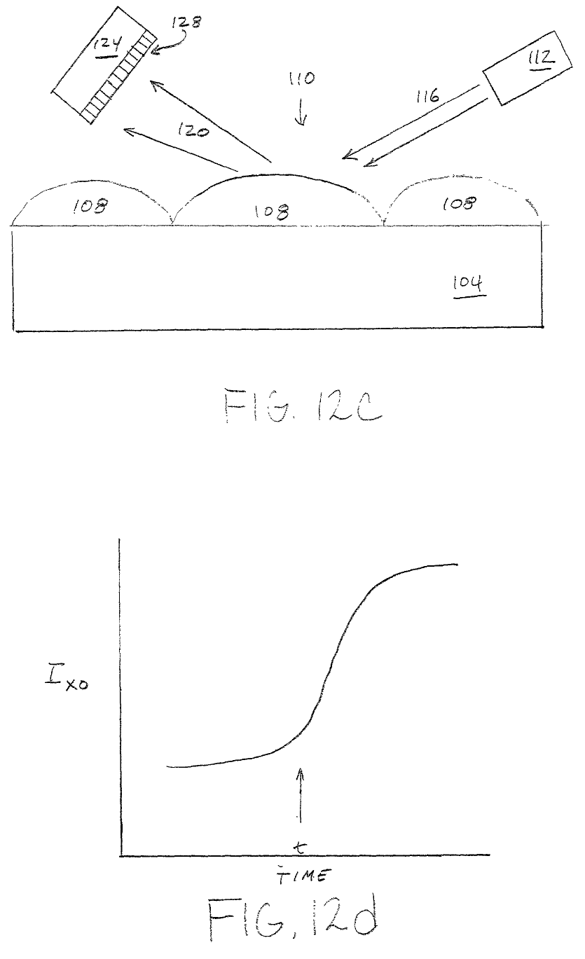

FIGS. 12a-12d illustrate one type of embodiment of this invention for monitoring silicide formation. FIG. 12a is a drawing that depicts a silicon substrate 104 having islands of TiSi₂ 108 thereon. Source 112 of electromagnetic radiation projects incident electromagnetic beam 116 at substrate 104 with beads 108. The electromagnetic radiation is reflected by surface 110 and reflected beam 120 is detected by detector 124. When features on surface 110 are smaller than the wavelength of incident beam 116, beam 116 is reflected with little scattering, and reflected beam 120 impinges on only a relatively few number of individual photodetectors 128 of detector 124.

FIG. 12b is a graph illustrating the relationship between time of growth on the horizontal axis and the intensity of scattered light at a wavenumber Xo for TiSi₂ features smaller than the wavelength of incident light beam 116. As the islands 108 increase in size, there is little increase in the intensity of scattered light, Ixo. However, as the islands coalesce to form larger beads 108 having sizes comparable to and/or larger than the wavelength of incident beam 116 (FIG. 12c), the scattering of light can increase abruptly (FIG. 12d). The abrupt increase in the intensity of scattered light at time t is an indication that the sizes of beads 108 grew to sizes sufficiently large to scatter the light of beam 116. Thus, the increase in Ixo is an indication that the average feature size was larger than about the wavelength of the light of incident beam 116.

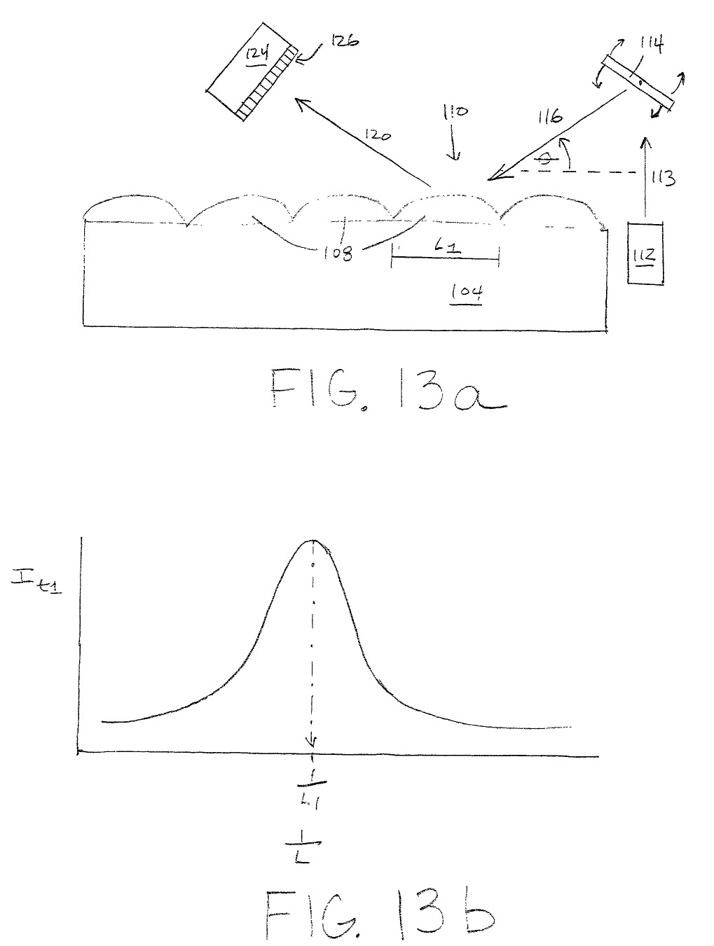

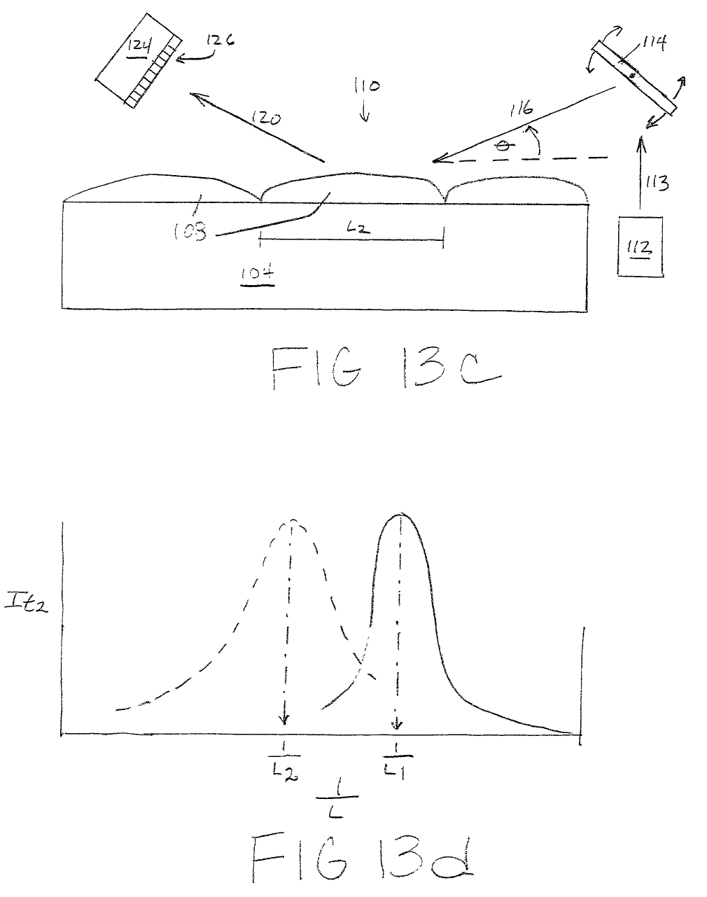

In other embodiments of this invention, instead of a single wavelength of incident light being used, one can use a range of wavelengths of incident light to monitor the intensity of light scattering as a function of the bead size. FIGS. 13a-FIG. 13d depict this type of embodiment.

FIG. 13a is a drawing depicting, at an early time (t₁) during deposition, a semiconductor wafer having a silicon substrate 104 and relatively small beads 108 having length L₁ thereon. Light source 112 is located so as to project emitted light beam 113 towards a mirror 114 that can rotate relative to the emitted light beam and the surface of the substrate (curved arrows). The emitted light beam 113 is reflected by mirror 114 and is projected as incident beam 116 onto the surface of the substrate at an angle θ that depends upon the orientation of the mirror 114. The orientation of mirror 114 is varied to provide a range of angles of incidence of the light beam with the surface of the substrate. Upon striking the surface of the substrate, a portion of the incident light beam 116 is scattered by surface 110 and the intensity of the scattered light is measured using a detector 124 having a plurality of photodetector cells 126. As the wavelength is cycled through the range chosen, the intensity of scattered light at time 1 (Iₜ₁) will change, having a maximum intensity that is dependent on the wavelength corresponding to the feature sizes analyzed.

FIG. 13b shows the relationship between the reciprocal of the feature size (1/L) and the intensity of scattered light at time 1 (1ₜ₁) as a function of the wavelength of incidence for a surface having relatively small feature sizes as in FIG. 13a. The peak intensity of the scattered light observed has a maximum at a certain value of 1/L corresponding to the feature size that predominates under these conditions.

FIG. 13c depicts a similar situation as shown in FIG. 13a, except that the average feature size L₂ is larger than L₁ shown in FIG. 13a. Otherwise, the relationships between the substrate surface and the light monitoring equipment are the same. FIG. 13d is a graph illustrating the intensity of the scattering of incident light at time 2 (lₜ₂) as a function of the feature size variable 1/L for the surface depicted in FIG. 13c. The peak intensity of scattering is shown shifted to the left (dashed line), toward smaller values of 1/L, reflecting larger feature sizes. The corresponding trace (solid line) for the situation depicted in FIG. 13b is shown for comparison.

Using the light monitoring methods described above, any phase transformation that is accompanied by a change in surface roughness or feature sizes can be analyzed. Such phase transformation include crystallization and annealing, as well as deposition of films by sputtering or physical deposition, as well as films deposited by vapor phase deposition, such as chemical vapor deposition (CVD). Using these monitoring methods, the conditions of silicidation or other processes, including temperature, pressure, component concentration, and other process variables can be selected to provide the desired texture of a material being deposited.

Moreover, because these methods can be carried out during deposition and/or annealing, the progress of the process can be easily monitored in situ, and when the desired surface morphology is attained, the process can be stopped. The ability to provide in situ, real time monitoring can permit the more rapid manufacture of semiconductors surfaces having desired texture.

### IV. High Sensitivity, High Accuracy Monitoring of Processing Temperatures

As semiconductor feature sizes become smaller and as high manufacturing through-put becomes increasingly important, careful regulation of process temperature is increasingly important. As new semiconductor materials become incorporated into devices, new methods for monitoring temperature are needed.

For example, copper can be used as a conductive metal because of its desirable properties, including low electrical resistance. However, copper can oxidize at relatively low temperatures. Therefore, to prevent oxidation during semiconductor processing, it can be desirable to keep processing temperatures lower than those that are acceptable for manufacturing semiconductor devices using aluminum or titanium. Moreover, as feature sizes decrease, it becomes more important to more accurately know the temperature that exists on the surface of the wafer where the processes are occurring. Prior methods of measuring ambient temperature in heated ovens are too inaccurate because the ambient temperature is not necessarily the same as the temperature on the surface of the semiconductor wafer. Further, measurements of wafer temperature using thermocouples can be inaccurate because thermocouples are typically placed on the back sides of the wafers, and are generally large. Moreover, in rapid thermal processing, or RTP procedures, the overall temperatures of the oven and wafer do not necessarily reflect the temperature of the semiconductor surface being treated.

Thus, in certain embodiments of this invention, a manufacturer can accurately predict the temperature at the wafer surface by calibrating the treatment apparatus using semiconductor wafers having surfaces of metal alloys on the surface. Alloys are selected on the basis of there being a reproducible temperature at which the particular alloy undergoes a phase transition that is accompanied by a change in electrical sheet resistance (“Rₛₕ”).

To apply this method to calibrating heating systems for semiconductor manufacturing, first one can select a temperature for the process step desired. Once the temperature is selected, a metal alloy is selected that has a phase transition temperature close to the processing temperature selected. In situations in which it is desirable to keep the temperature below a certain critical temperature (T_{c}), is can be useful to select alloys which have phase transition temperatures below that critical temperature. The selection of an alloy can be made from information available in the art, for example, the CRC Handbook of Chemistry and Physics, 75^{th} Edition, incorporated herein fully by reference.

Binary or ternary metal alloys can be especially desirable because of their relatively low cost and ready availability, although alloys of more than three metals can also be used. Byway of example only, a ternary alloy comprising 98% Al/1% Cu/1% Ge have an increase in Rh of up to about 15% when heated to a temperature of about 250° C. for about 24-48 hours. The phenomenon is accelerated for samples containing more Ge, because increasing the Ge content can lower the phase transition temperature, Tc. Other examples of binary alloys include Al/Li alloys. Concentrations of Li as low as about 0.3% in an alloy can undergo a phase transition at a temperature of about 300° C. when exposed for long periods of time (e.g., days). Increasing the concentration of Li can increase the sensitivity of Rₛₕ and can provide a very fast response time.

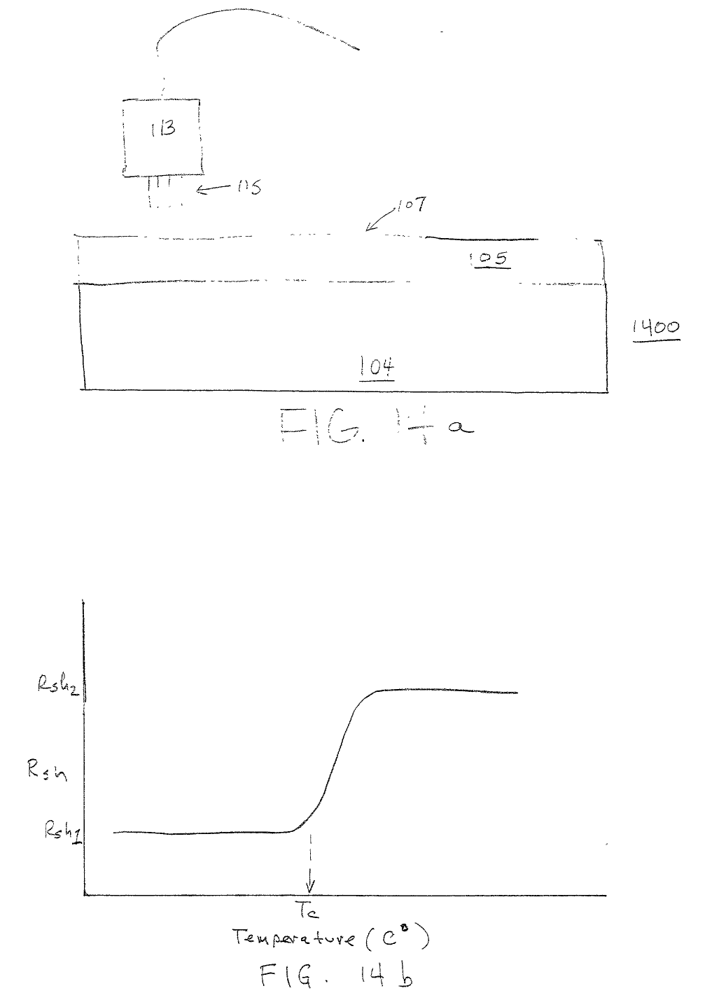

FIG. 14a is a drawing illustrating a temperature calibrating wafer and apparatus of this invention. Typically, a semiconductor wafer 1400 suitable for this method comprises a silicon substrate 104 having a thickness in the range of about 100 μm to about 1000 μm. Then, a layer comprising a binary or ternary metal alloy 105 is deposited on the surface of silicon substrate 104. The layer 105 can have a thickness in the range of about 100 Å to about 5 μm, alternatively about 1 μm. Layer 105 can be deposited by any convenient means, including but not limited to physical vapor deposition (PVD) chemical vapor deposition (CVD) or by ion bombardment. It can also be desirable to control the conditions of formation of the layer 105 by removing oxygen or other oxidants from the system to increase the uniformity of the alloy film, or by carrying out the alloy deposition in an inert gas that is compatible with the alloy components used. For example, nitrogen or the noble gases, helium, neon, argon, xenon can be used.

Disposed above the surface 107 of the alloy surface 105 is a device 113 for measuring Rₛₕ having a plurality of probes 115. To measure sheet resistance, the probe array 115 is placed in electrical contact with surface 107 to be analyzed, and the flow of electrical current is monitored using the two inner probes. Any conventional probe array is suitable, and can include, by way of example, a 4-point probe from Four Dimensions, Inc. of Hayward, Calif., or alternatively, a system produced by Hewlett Packard, Palo Alto, Calif. The probe separation distance can be in the range of about 0.1 -10 mm per array, and can be adjusted as desired. In general, a voltage difference can be applied between the two outer probes. This voltage, herein referred to as the “input voltage” can be in the range of 0.1 milliVolts (mV) to about 1 Volt, alternatively from about 50 mV to about 200 mV, and in alternative embodiments, about 100 mV.

FIG. 14b illustrates the use of the system depicted in FIG. 14a to evaluate the temperature on the surface 107 of the semiconductor wafer. FIG. 14b is a graph depicting sheet resistance (Rₛₕ) as a function of the temperature (T) in °C. Below the critical temperature (T_{c}), sheet resistance is relatively low (Rₛₕ₁), and is relatively constant as temperature varies. As the temperature increases above T_{c}, the Rₛₕ increases abruptly and reaches a new, higher value (Rₛₕ₂). For certain alloys, the increase in Rₛₕ can be due to a phase separation, wherein the previously well-mixed metal alloy can separate into distinct phases of individual metals. From the measured current and the input voltage, the sheet resistance R_{Sh} can be derived from Ohm's law, relating the input voltage V the current I to the resistance R according to the following formula: V=IR. Replicate measurements are made in from about 1 to about 100 different sites around the wafer, with fewer measurements being needed to determine the overall resistance, and more measurements being needed to determine the uniformity of sheet resistance. In alternative embodiments, it can be desirable to make between about 5 and about 50 measurements, and in yet other embodiments, it can be desirable to measure Rₛₕ at from 10 to 20 points, and in yet other embodiments, about 9 measurements can provide sufficient reproducibility and accuracy.

One distinct advantage of the methods of this invention is that the Tc can be determined to a fraction of a degree C. Also, below the Tc, the non-uniformity of Rₛₕ is generally low, being on average a few % of the Rₛₕ. However, as the Tc is approached from below, the non-uniformity of Rₛₕ will increase, often as a step-function or spike in non-uniformity, followed by a higher average value of non-uniformity. These phenomena may be due to the change in structure of the alloy, from a relatively homogeneous mixture to a phase-separated structure having different domains reflecting the different chemical constituents of different parts of the film. However, other mechanism may account for the phenomena, and the present invention is not intended to be limited to any particular theory or mechanism for operability.

By the use of these methods, the effective surface temperature of a semiconductor wafer can be calibrated closely as a function of input variables, such as input voltage for resistive heater, or power output for RTP devices. Once the relationship between input variables and the effective surface temperatures have been determined, semiconductor processing can be carried out without the need for monitoring of the ambient temperature in the oven.

Moreover, it yet other embodiments of this invention in which the alloys have physical structures such as islands or beads, the phase transition can be monitored using optical methods described above for monitoring silicide formation.

It is to be understood that the aforementioned description and examples are not intended to be limiting. Other embodiments of this invention are possible within the ordinary skill, and modifications of the described methods and films are within the ordinary skill of workers in the art, and all such modifications are considered to be part of this invention.

### Industrial Applicability

Certain of the methods of this invention for manufacturing barrier layers on metal provide easy, effective ways for protecting metal features from becoming contaminated with dopants during the manufacture and use of semiconductor devices. By decreasing dopant diffusion into the metal layers, certain of the barrier layers can decrease dopant diffusion into the metal, and thereby can decrease the formation of metal salts. By inhibiting the formation of metal salts, the formation of voids can be reduced, and delamination can be substantially decreased. By inhibiting these defects in semiconductor devices, the useful lifetimes of devices can be increased. Additionally, the use in certain embodiments of the invention, of nitrogen rich plasmas, ion implantation, and electromagnetic radiation methods for forming barrier layers can be incorporated easily into existing manufacturing protocols. The use of power law behavior of metal films, and the monitoring of phase transitions of semiconductor materials can increase the reliability and accuracy of semiconductor manufacturing, and can result in decreased cost and increased reliability and lifetimes of devices made using certain embodiments of the methods of this invention.

We claim:

1. A method for reducing diffusion of dopant ions from a doped dielectric layer into a metal layer, comprising:
(a) depositing on said metal layer, a diffusion barrier; and then
(b) depositing a layer of doped dielectric material on said diffusion barrier.

2. The method of claim 1, wherein said diffusion barrier is a layer of metal nitride.

3. The method of claim 1, wherein said diffusion barrier is a layer of metal oxynitride.

4. The method of claim 2, wherein said layer of metal nitride has a thickness in the range of about 10 Å to about 1000 Å.

5. The method of claim 2, wherein said layer of metal nitride has a thickness in the range of about 50 Å to about 350 Å.

6. The method of claim 2, wherein said layer of metal nitride has a thickness of about 100 Å.

7. The method of claim 2, wherein said metal nitride is formed using a nitrogen rich radiofrequency (rf) plasma.

8. The method of claim 7, wherein radiofrequency plasma is formed using hydrogen and nitrogen gases having a ratio in the range of about 0.1:1 to about 4:1.

9. The method of claim 7, wherein radiofrequency plasma is formed using hydrogen and nitrogen gases having a ratio in the range of about 0.5:1 to about 2:1.

10. The method of claim 7, wherein radiofrequency plasma is formed using hydrogen and nitrogen gases having a ratio of about 3:2.

11. The method of claim 7, wherein the rf plasma power is in the range of about 100 Watts per 8 inch wafer to about 1000 Watts per 8 inch diameter wafer.

12. The method of claim 7, wherein the rf plasma power is in the range of about 400 Watts per 8 inch wafer to about 800 Watts per 8 inch diameter wafer.

11. The method of claim 5, wherein the rf plasma power is about 750 Watts per 8 inch wafer.

13. The method of claim 7, wherein the rf plasma is generated in the presence of a noble gas.

14. The method of claim 13, wherein said noble gas is selected from the group consisting of helium, neon, argon, krypton and xenon.

15. The method of claim 7, wherein the pressure in the plasma chamber is in the range of about 100 milliTorr to about 50 Torr.

16. The method of claim 7, wherein the pressure in the plasma chamber is in the range of about 1 Torr to about 10 Torr.

17. The method of claim 7, wherein the pressure in the plasma chamber is about 4 Torr.

18. The method of claim 1, wherein the step of depositing a layer of doped dielectric material is carried out at a deposition temperature in the range of about 200° C. to about 450° C.

19. The method of claim 1, wherein said doped dielectric layer is selected from the group consisting of fluorine doped silicate glass (FSG), phosphorous doped silicate glass (PSG), boron doped silicate glass (BSG), and boron phosphorous doped silicate glass (BPSG).

20. The method of claim 2, wherein said metal nitride layer comprises a metal selected from the group consisting of aluminum, tantalum and titanium.

21. A method for reducing diffusion of dopant ions from a dielectric layer into a metal layer, comprising:
(a) depositing on said metal layer, a nitrogen rich metal nitride layer; and
(b) depositing a layer of doped dielectric material on said nitrogen rich metal nitride layer.

22. The method of claim 21, wherein said metal nitride layer is made using a radiofrequency (rf) method using at least one variable selected from (a) a hydrogen:nitrogen ratio in the range of about 0.1:1 to about 4:1, (b) an rf power in the range of about 100 Watts per 8 inch wafer to about 1000 Watts per 8 inch diameter wafer, (c) a pressure in the plasma chamber in the range of about 100 milliTorr to about 50 Torr, and (d) a deposition temperature in the range of about 200° C to about 450° C.

23. The method of claim 21, wherein the metal nitride is selected from the group consisting of aluminum nitride, titanium nitride, and tantalum nitride.

24. A method for reducing diffusion of dopant ions from a dielectric layer into a metal layer, comprising:
(a) providing a substrate;
(b) depositing over said substrate, a metal layer from the group consisting of aluminum, titanium, tantalum and aluminum/tantalum;
(c) forming a metal nitride using a nitrogen rich plasma using at least one variable selected from the group consisting of:
(i) a hydrogen:nitrogen ratio in the range of about 0.1:1 to about 4:1;
(ii) an rf power in the range of about 100 Watts per 8 inch wafer to about 1000 Watts per 8 inch diameter wafer;
(iii) a pressure in the plasma chamber in the range of about 100 milliTorr to about 50 Torr; and a deposition temperature in the range of about 200° C. to about 450° C.;and
(d) depositing on said metal nitride layer, a layer of doped dielectric material selected from the group consisting of fluorine doped silicate glass (FSG), phosphorous doped silicate glass (PSG), boron doped silicate glass (BSG), and boron phosphorous doped silicate glass (BPSG).

25. A method for decreasing mechanical stress at an interface between two metal layers, comprising:
(a) providing a substrate having a layer of a first metal thereon;
(b) forming, using a nitrogen rich plasma, a layer of first metal nitride on said first metal; and
(c) forming a layer of a second metal on said layer of first metal nitride.

26. A method for forming a semiconductor device, comprising the steps of:
(a) providing a substrate having a layer of pad oxide thereon;
(b) forming a semiconductor stack comprising the steps of forming:
(i) layer of titanium on said layer of pad oxide;
(ii) forming a layer of titanium nitride on said layer of titanium;
(iii) forming a layer of aluminum on said layer of titanium nitride;
(c) etching, in said stack, a trench having sidewalls;
(d) forming a layer of nitrogen rich nitride on said sidewalls; and
(e) filling said trench with a layer of doped dielectric material.

27. A method for forming a semiconductor device, comprising the steps of:
(a) providing a substrate having a layer of pad oxide thereon;
(b) forming a semiconductor stack comprising the steps of forming:
(i) layer of aluminum/tantalum having a ratio of about 50%:50% on said layer of pad oxide;
(ii) forming a layer of titanium nitride on said layer of aluminum/tantalum;
(iii) forming a layer of aluminum on said layer of titanium nitride;
(c) etching, in said stack, a trench having sidewalls;
(d) forming a layer of nitrogen rich nitride on said sidewalls; and
(e) filling said trench with a layer of doped dielectric material.

27. The method of claim 2, wherein said barrier layer is formed using electromagnetic radiation.

28. The method of claim 2, wherein said barrier layer is formed using nitrogen ion implantation.

29. A semiconductor device, comprising:
a gate;
a layer of dielectric material over said gate;
and a metal via through said layer of dielectric material, said via in contact with said gate, said via having a layer of metal nitride separating said via from said layer of dielectric material.

30. A semiconductor device, comprising:
(a) a substrate having a source region and a drain region formed therein;
(b) a gate, having sidewall spacers, over said substrate and over at least a portion of said source region and said drain region;
(c) layers of silicide over said source region, said drain region and said gate;
(d) a layer of dielectric material over said gate;
(e) a metal via in contact with said gate, said via extending through said layer of dielectric material; and
(f) a layer of metal nitride between said via and said layer of dielectric material.

31. A method for determining the thickness of a layer of a deposited conductive material, comprising the steps of:
(a) selecting at least one deposition condition selected from the group consisting of temperature, reactant concentration, power density, and deposition time;
(b) determining the power law relationship between film thickness and sheet resistance for the deposition condition selected in step (a); and
(c) based on the results of step (b), monitor sheet resistance during deposition until a desired sheet resistance is achieved.

32. The method of claim 31, wherein the power law relationship determined in step (b) is about −1.3.

33. A method for determining the alternations in the surface roughness of the surface of a semiconductor film, comprising the steps of:
(a) directing a beam of electromagnetic radiation at a surface of said semiconductor film;
(b) measuring the scattering of said electromagnetic radiation;
(c) carrying out a process for altering the surface roughness of said film; and
(d) repeating steps (b) and (c) until a desired degree of scattering is achieved.

34. The method of claim 33, wherein step (c) is a process selected from the group consisting of deposition and annealing.

35. The method of claim 33, wherein step (c) is a deposition step.

36. A method for calibrating a semiconductor heating device, comprising the steps of:
(a) depositing onto a semiconductor substrate, a layer of an alloy having a phase transition temperature associated with a change in sheet resistance;
(b) exposing said alloy to a first temperature;
(c) measuring the sheet resistance of said alloy;
(d) exposing said alloy to a temperature different from said first temperature;
(e) repeating step (c); and
(f) repeating steps (d) and (e) until said sheet resistance changes by more than a predetermined value.

37. The method of claim 36, wherein said alloy is a binary or ternary metal alloy.

38. The method of claim 36, wherein said alloy is comprised of metals selected from the group consisting of aluminum, copper, germanium and lithium.

39. The method of claim 36, wherein said alloy is comprised of about 98% aluminum, about 1% copper and about 1% germanium.

40. The method of claim 36, wherein said alloy is comprised of aluminum and lithium.

41. The method of claim 36, wherein said alloy has a phase transition temperature below about 350° C.

42. The method of claim 36, wherein the thickness of said layer of alloy is in the range of about 100 Å to about 5 μm.

43. The method of claim 36, wherein steps (b) and (d) are carried out in an inert gas.

44. The method of claim 36, wherein steps (b) and (d) are carried out in a gas selected from the group consisting of nitrogen, helium, neon, argon or xenon.

45. The method of claim 36, wherein said heating device is selected from an oven and a rapid thermal processing device.
